(19) United States
(12) Patent Application Publication
(10) Pub. No.: US 2015/0217657 A1
(43) Pub. Date: Aug. 6, 2015

(54) DEVICE AND METHOD FOR REDUCING PEAK LOAD OF ELECTRIC ENERGY WITHIN BUILDING USING ELECTRIC VEHICLE

(71) Applicant: Electronics and Telecommunications Research Institute, Daejeon (KR)

(72) Inventors: Shin Yuk KANG, Seoul (KR); Youn Kwae JEONG, Daejeon (KR); Il Woo LEE, Daejeon (KR)

(73) Assignee: Electronics and Telecommunications Research Institute, Daejeon (KR)

(21) Appl. No.: 14/613,391

(22) Filed: Feb. 4, 2015

(30) Foreign Application Priority Data
Feb. 5, 2014 (KR) 10-2014-0012941

(51) Int. Cl. B60L 11/18; H02J 3/32; G01R 21/00

(52) U.S. Cl. CPC B60L 11/1842; G01R 21/00; B60L 11/1848; B60L 11/1861; H02J 3/32

(57) ABSTRACT

Disclosed are a device and method for reducing a peak load of electric energy within a building using an electric vehicle (EV) and a device for managing the electric energy of the EV. The device includes, for control of the electric energy within the building using electric energy of the EV, a vehicle information extraction section connected to the EV and configured to extract vehicle information of the EV, an energy demand amount prediction section configured to predict a demand amount of the electric energy within the building, and a charging/discharging schedule determination section configured to determine a charging/discharging schedule of the EV based on the vehicle information and the demand amount of the electric energy within the building.

### CLAIM FOR PRIORITY

This application claims priority to Korean Patent Application No. 2014-0012941 filed on Feb. 5, 2014 in the Korean Intellectual Property Office (KIPO), the entire contents of which are hereby incorporated by reference.

### BACKGROUND

1. Technical Field

Example embodiments of the present invention relate in general to technology for reducing a peak load of electric energy within a building and more specifically to technology for performing charging and discharging through different schedules in a peak time and a non-peak time as a method of utilizing batteries provided in a plurality of electric vehicles (EVs) parked in a large-size building or building as an energy storage system (ESS).

2. Related Art

EVs capable of obtaining power energy by rotating a motor with electricity stored in a battery without obtaining power energy from combustion of fossil fuels were manufactured before gasoline vehicles in 1873. However, the EVs were not commercialized because of a heavy weight of the battery and a long time required for charging, and the EVs have started to be developed from 1990's because a pollution problem has gradually become severe.

In addition, in order to overcome the impracticality of the EV due to the above-described problem, research and development on a hybrid electric vehicle (HEV), a fuel cell vehicle (FCV), and the like that are driven by performing charging with electricity using a rechargeable auxiliary engine have continuously been done. On the other hand, in Korea, the utilization of EVs is being accelerated with the promotion of EV business for the aim of entering the world's four major powers in 2020.

When it is necessary to charge a battery of an EV to be driven, the EV is charged using a dedicated charging station or a charging facility. As technologies for this, there are middleware technology as a platform of EV charging/discharging integration management, uninterruptable power supply (UPS) within a parking area, power system technology through an incoming panel and a panel board, demand management and external power interworking technology, distributed power switching technology, and the like.

There is a problem in that it is necessary to increase application power and load to power of a building so that a plurality of EVs are simultaneously charged with electric energy within the same building and other power demand of the building is satisfied if there is no peak power stabilization function because electric energy is used in buildings or charging stations. Thus, it is necessary to increase the number of power generation facilities or the use of electric energy within the building may be limited.

The lack of electric energy may be described as a peak load. When the electric energy is insufficient, a solution is only a method of increasing the supply amount of electric energy (constructing an additional power generation station) or decreasing the demand of electric energy. In order to reduce the demand of the electric energy, a method of reducing the peak load in which the demand is concentrated in a daytime zone through facility control or the like in the building itself is used currently. Although there is an attempt to perform a method in which electric energy of the energy storage device is used in the daytime zone in which the demand is high after the energy storage device such as an ESS is charged with electric energy in large-size buildings in the future, it is difficult to apply this method because the cost of the energy storage device such as the ESS is high and a significant space is required for installation of the energy storage device.

This problem may be solved without additionally constructing a power generation station if it is possible to store electric energy from batteries of EVs in a nighttime zone in which a load is small so as to utilize the stored electric energy in a daytime zone in conjunction with an electric energy management system of a building after getting into office and recharge the EVs with electric energy after a peak time so that the recharged EVs are available after getting out of office.

### SUMMARY

Accordingly, example embodiments of the present invention are provided to substantially obviate one or more problems due to limitations and disadvantages of the to related art.

Example embodiments of the present invention provide a device and method for reducing a peak load and reducing a use amount of electric energy within a building by causing a movable energy storage device such as an EV to be linked to an electric energy management system of the building by eliminating the restriction in which only an internal energy management system of the building performs a method of reducing a peak load of electric energy within the building.

Furthermore, it is possible for a system for managing electric energy within a building to utilize EVs as an electric energy storage device and recharging the EVs with electric energy when a peak time has elapsed after the electric energy of the EVs was used without use of external power at the time of a peak load and easily cope with a peak load (high-cost energy use) without constructing an additional power generation station or introducing an additional system for reducing electric energy within the building by assigning the benefit of parking fee reduction and additional benefits in return for the use of electric energy of the EVs. Example embodiments of the present invention contribute to national electric energy load shifting by providing core methods in implementing this system.

In some example embodiments, a device for reducing a peak load of electric energy within a building includes: for control of the electric energy within the building using electric energy of an EV, a vehicle information extraction section connected to the EV and configured to extract vehicle information of the EV; an energy demand amount prediction section configured to predict a demand amount of the electric energy within the building; and a charging/discharging schedule determination section configured to determine a charging/discharging schedule of the EV based on the vehicle information and the demand amount of the electric energy within the building.

Here, the vehicle information may include electric energy storage information and driving information of the EV.

Here, the charging/discharging schedule determination section may calculate a total amount of electric energy capable of being supplied from the EV in the demand amount of the electric energy within the building.

Here, the total amount of electric energy capable of being supplied may be calculated based on the electric energy storage information and driving information of the EV.

The device may further include: an energy exchange section configured to receive the electric energy of the EV from an electric storage facility of the building based on the charging/discharging schedule when the peak load of the electric energy within the building occurs.

Here, the energy exchange section may cause the EV to be charged with the electric energy of the electric storage facility based on an amount of the electric energy received from the EV.

The device may further include: an energy exchange information management section configured to record electric energy exchange information between the building and the EV.

Here, the energy exchange information management section may calculate an amount of money to be paid to a user of the EV based on the electric energy exchange information.

In other example embodiment, a method of reducing a peak load of electric energy within a building in a device for controlling the electric energy within the building using electric energy of an EV includes: extracting vehicle information of the EV though a connection to the EV; predicting a demand amount of the electric energy within the building; and determining a charging/discharging schedule of the EV based on the vehicle information and the demand amount of the electric energy within the building.

Here, the vehicle information may include electric energy storage information and driving information of the EV.

Here, the determining of the charging/discharging schedule may include: calculating a total amount of electric energy capable of being supplied from the EV in the demand amount of the electric energy within the building.

Here, the total amount of electric energy capable of being supplied may be calculated based on the electric energy storage information and driving information of the EV.

The method may further include: after the determining of the charging/discharging schedule, receiving the electric energy of the EV from an electric storage facility of the building based on the charging/discharging schedule when the peak load of the electric energy within the building occurs.

The method may further include: after the receiving of the electric energy of the EV from the electric storage facility of the building, causing the electric energy of the electric storage facility to be provided to the EV based on an amount of the received electric energy of the EV.

The method may further include: recording electric energy exchange information between the building and the EV.

The method may further include: after the recording of the electric energy exchange information, calculating an amount of money to be paid to a user of the EV based on the electric energy exchange information.

In still other example embodiments, a device for managing electric energy of an EV includes: a vehicle information transmission section connected to a charging/discharging socket and configured to transmit vehicle information of the EV to a device for reducing a peak load of electric energy within a building; and a charge/discharge amount recording section configured to record an amount of charge or discharge of electric energy through the charging/discharging socket and calculate a total amount of electric energy in predetermined period units.

Here, the vehicle information may include electric energy storage information and driving information of the EV.

According to the device and method for reducing the peak load of the electric energy within the building, it is possible to decrease power demand of a time zone in which the electricity fee is high by employing electric energy with which a battery of an EV is charged as electric energy within the building in a peak time in which electric energy supply and demand are peak and charging the battery of the EV with the electric energy supplied to the building when the peak time has elapsed using an EV energy management device.

Because a user of the EV may contribute to reduction of a peak load of the building through the battery of the EV through the above-described device and method, they may receive the benefit such as parking fee reduction and therefore the economy gain may be provided to both the building owner and the user.

Furthermore, a method of linking a movable electric energy storage device such as an EV to a system for managing electric energy within a building can contribute to a national energy reduction policy by reducing the peak load by eliminating the restriction in which a method of reducing the peak load of the electric energy within the building only depends upon an internal system of the building itself.

### BRIEF DESCRIPTION OF DRAWINGS

Example embodiments of the present invention will become more apparent by describing in detail example embodiments of the present invention with reference to the accompanying drawings, in which:

FIG. 1 is a block diagram illustrating an electric energy charging/discharging system within a general building and its components according to an example embodiment of the present invention;

FIG. 2 is a block diagram illustrating a device for reducing a peak load of electric energy within a building and its components according to an example embodiment of the present invention;

FIG. 3 is a block diagram illustrating a device for reducing a peak load of electric energy within a building and its components according to another example embodiment of the present invention;

FIG. 4 is a flowchart illustrating a method of reducing a peak load of electric energy within a building and its detailed steps according to an example embodiment of the present invention; and

FIG. 5 is a block diagram illustrating an EV energy management device and its components according to an example embodiment of the present invention.

### DESCRIPTION OF EXAMPLE EMBODIMENTS

Example embodiments of the present invention are disclosed herein. However, specific structural and functional details disclosed herein are merely representative for purposes of describing example embodiments of the present invention, however, example embodiments of the present invention may be embodied in many alternate forms and should not be construed as limited to example embodiments of the present invention set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, A, B, etc. may be used herein in reference to elements of the invention, such elements should not be construed as limited by these terms. For example, a first element could be termed a second element, and a second element could be termed a first element, without departing from the scope of the present invention. Herein, the term “and/or” includes any and all combinations of one or to more referents.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

The terminology used herein to describe embodiments of the invention is not intended to limit the scope of the invention. The articles “a,” “an,” and “the” are singular in that they have a single referent, however the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, items, steps, operations, elements, and/or components, but do not preclude the presence or addition of one or more other features, items, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

First, the terms used in the present specification are defined as follows.

The term “peak” generally refers to that when an upper peak (or lower peak) is shown in a value of Y when a value of X is varied and a value of Y is recorded with respect to measured amounts X and Y. In the electric energy, a power demand amount is referred to as a power load and the power load in a factory or home remarkably varies with a time zone in one day. A maximum value of the load during one day or a certain period may be referred to as a peak load. An important task is a method of reasonably managing the peak load in a power demand and supply plan, particularly, a power facility plan.

An electric storage facility is referred to as an electric storage in which electric energy is stored and used when necessary. A capacitor or condenser which is the most important element of the electric storage facility is a device in which electric charges are accumulated in an electronic circuit. This capacitor or condenser plays a role in charging or discharging with electric charge. In general, the capacitor or condenser is manufactured by designating two metal plates as electrodes and inserting a dielectric between the electrodes. When a voltage is applied to the two electrodes, negative charge is formed in a negative electrode and positive charge is formed in a positive electrode. Here, an amount of negative charge is the same as an amount of positive charge. At this time, an amount of electric charge is proportional to a voltage. When the electric capacitance of the capacitor or condenser is denoted by C, the voltage is denoted by V, and an amount of charge is Q, a relation formula Q=CV is established.

Hereinafter, preferred example embodiments according to the present invention will be described in detail with reference to the accompanying drawings.

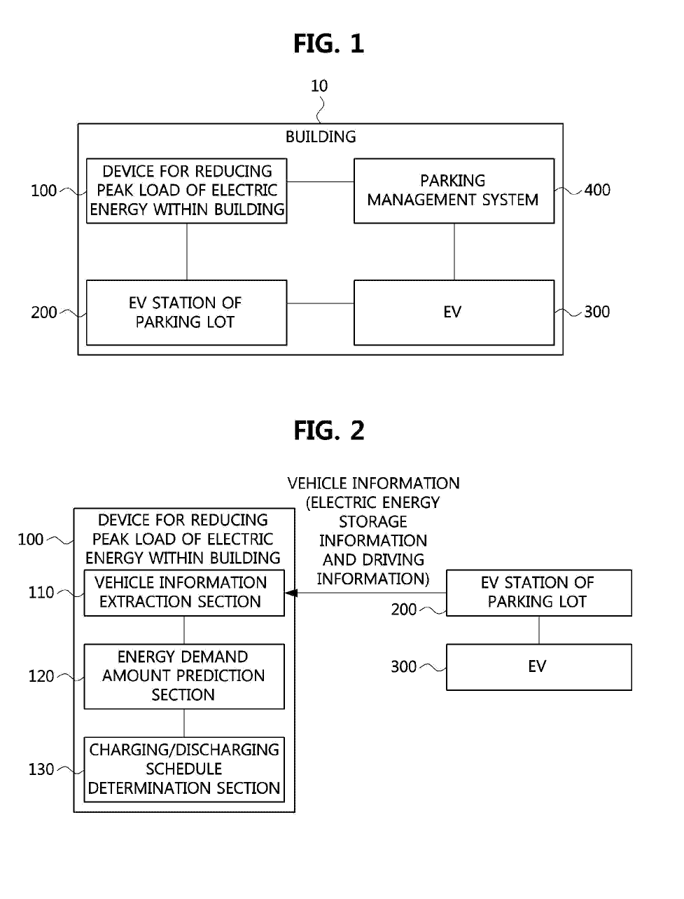

FIG. 1 is a block diagram illustrating an electric energy charging/discharging system within a general building 10 and its components according to an example embodiment of the present invention.

Under the assumption that EVs are already spread and a charging/discharging infrastructure for the EVs is constructed in each building, a corresponding procedure will be described. Various conventional methods may be utilized for a method of charging an EV at home after getting out of office and a load control method. An example in a situation in which charged EVs to be used for getting into office are parked in a building will be described.

Referring to FIG. 1, an EV station 200 capable of charging and discharging the EV 300 is provided in a parking lot within the building 10. If a charging/discharging socket provided in the EV station 200 is connected to the EV 300, the EV station 200 may charge and discharge the EV 300. In addition, necessary information between a device 100 for reducing a peak load of electric energy within the building and the EV 300 may be exchanged through the charging/discharging socket. It is possible to perform this information exchange through a wired/wireless communication network.

A parking management system 400 of the building 10 manages parking information for the parked EV 300. A parking period of the EV 300, identification information about the EV 300, user information, and the like may be included in the parking information. The parking management system 400 may exchange information through a connection of wired/wireless communication with the device 100 for reducing the peak load of the electric energy within the building.

Continuously referring to FIG. 1, the components of FIG. 1 are logical components rather than physical components and physical positions may be different in reality. For example, although the parking management system 400 may be independently present, the parking management system 400 may be included in the device 100 for reducing the peak load of the electric energy within the building. The EV station 200 of the parking lot may also be independently present or be included in the device 100.

Components of the device 100 for reducing the peak load of the electric energy within the building to be described later are logical components and positions of the components may be different in reality. For example, although the charging/discharging schedule determination section 130, which is a component of the device 100 for reducing the peak load of the electric energy within the building, may be located in the device 100, the charging/discharging schedule determination section 130 may be located in the EV station 200 of the parking lot.

A process in which the agreement of the user of the EV 300 is made so that the EV 300 is utilized in the above-described system is essential. It is necessary to utilize electric energy through a procedure or method according to the present invention with respect to only the EV 300 of which the user had made the agreement. The user who agreed on the utilization receives the benefit of parking feed reduction in the building 10 or receives a fee for the use of the electric energy of the EV 300.

FIG. 2 is a block diagram illustrating the device 100 for reducing the peak load of the electric energy within the building and its components according to an example embodiment of the present invention.

Referring to FIG. 2, the device 100 for reducing the peak load of the electric energy within the building may include, for control of the electric energy within the building using electric energy of the EV 300, a vehicle information extraction section 110 connected to the EV 300 and configured to extract vehicle information of the EV 300, an energy demand amount prediction section 120 configured to predict a demand amount of the electric energy within the building, and a charging/discharging schedule determination section 130 configured to determine a charging/discharging schedule of the EV 300 based on the vehicle information and the demand amount of the electric energy within the building. The vehicle information may include electric energy storage information and driving information of the EV 300.

A demand amount of electric energy within the building 10 may be calculated based on an energy management plan of the building 10. A demand amount response (DR) information of the building 10, existing energy use information, and information about an energy use amount per previous unit time, and the like may be referred to.

After the EV 300 is charged in a nighttime zone in which a load of electric energy is small, the EV 300 may be parked in the building 10 for getting into office in the morning of the next day and connected to a charging/discharging socket of a parking lot of the building 10. At this time, the vehicle information such as the electric energy storage information and the driving information of the EV may be transferred to the device 100 for reducing the peak load of the electric energy within the building.

The electric energy storage information may include information (maximum capacity) about an amount of electric energy with which the EV may be fully charged, information about an amount of current charge energy, information (charge/discharge amount per unit time) about a time required for charging/discharging with electric energy, and information about a charge/discharge amount history specific to a previous unit period.

The driving information may include driving distance information at the time of getting into office and getting out of office, daily driving pattern information, and fuel efficiency information.

The charging/discharging schedule determination section 130 may calculate a total amount of electric energy capable of being supplied from the EV 300 in a demand amount of electric energy within the building and the total amount of electric energy capable of being supplied may be calculated based on the electric energy storage information and the driving information of the EV 300.

The energy demand amount prediction section 120 may predict electric energy to be used in the building 10 today based on the vehicle information collected according to each EV 300. The charging/discharging schedule determination section 130 performs a function of analyzing a total amount of available electric energy through electric energy with which the EVs 300 are charged. For example, the EV 300 having much electric energy is preferentially selected as a target to be utilized based on an amount of electric energy with which the EVs 300 are currently charged. It is possible to create a time-specific schedule for utilizing electric energy stored in the EV 300 by calculating an amount of electric energy necessary according to a driving distance at the time of getting out of office and considering an amount of electric energy necessary according to a daily driving pattern and a time necessary to recharge the EV with electric energy within the building so that the EV 300 may be driven again.

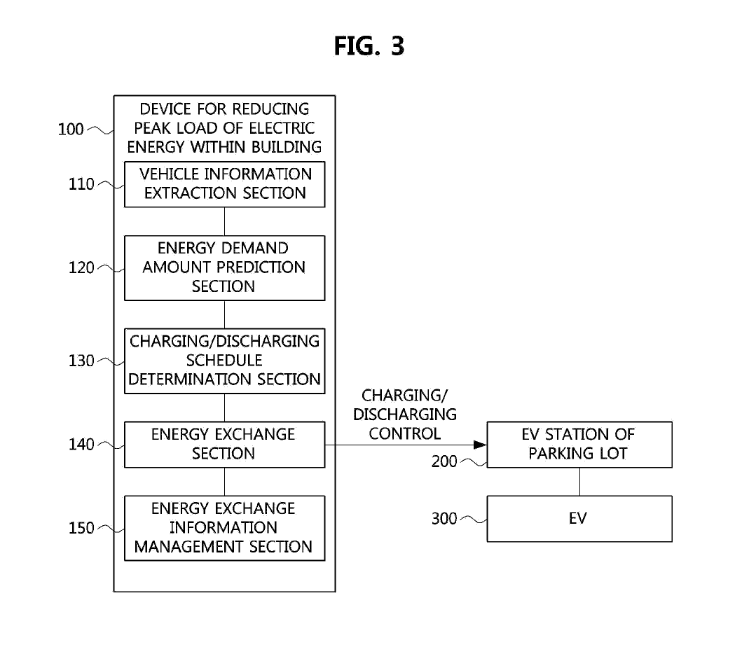

FIG. 3 is a block diagram illustrating a device 100 for reducing a peak load of electric energy within a building and its components according to another example embodiment of the present invention.

Referring to FIG. 3, the device 100 for reducing the peak load of the electric energy within the building may further include an energy exchange section 140 configured to receive electric energy of the EV 300 from an electric storage facility of the building 10 based on the charging/discharging schedule when the peak load of the electric energy within the building occurs.

Electric energy stored in the EV 300 is utilized as electric energy within the building when the peak load occurs according to the charging/discharging schedule created by the charging/discharging schedule determination section 130. The peak load may indicate a point at which a demand amount of electric energy is maximal. The occurrence of the peak load may be determined when a demand amount of electric energy is greater than a predetermined threshold value after the predetermined threshold value is specified. That is, when the demand amount of electric energy reaches about a maximum amount, the occurrence of the peak load may be determined.

When the predetermined threshold value is specified, an energy management plan of the building, existing energy use information, information about demand and supply amounts specified in a contracted with an electric power company, vehicle information of an EV, and the like may be referred to.

The energy exchange section 140 may cause the EV 300 to be charged with electric energy of the electric storage facility based on an amount of electric energy received from the EV 300.

After a peak load time, a recharging procedure may be performed based on an amount of electric energy received from the EV 300 when the electric energy of the EV 300 is utilized as electric energy within the building. This progresses in the form in which each EV is charged with electric energy by making a schedule considering the time of getting out of office based on each EV-specific charging time previously collected. That is, a recharging schedule is created based on vehicle information and electric energy storage information even at the time of recharging and a recharging operation may be performed based on the created recharging schedule.

The device 100 for reducing the peak load of the electric energy within the building may further include an energy exchange information management section 150 configured to record electric energy exchange information between the building and the EV 300. In addition, the energy exchange information management section 150 may calculate an amount of money to be paid to the user of the EV 300 based on electric energy exchange information.

The energy exchange information management section 150 may record an operation in which the energy exchange section 140 utilizes electric energy of the EV 300 and recharges the EV 300 according to the above-described charging/discharging schedule as an electric energy use history of the EV 300. In addition, an amount of money to be paid to the user of the EV 300 can be calculated based on the above-described electric energy use history according to an identifier (ID) which is identification information of the EV 300, a time in which the electric energy of the EV 300 is used as the electric energy of the building, an amount of used electric energy, a degree of contribution for a total reduction amount of electric energy within the building, an amount of money into which the electric energy is converted, and the like.

A procedure of calculating a parking fee and subtracting the calculated parking fee from an amount of money into which used electric energy is converted in conjunction with the parking management system when the user of the EV 300 gets out of office and separately transferring the remaining amount of money to the vehicle user may be configured.

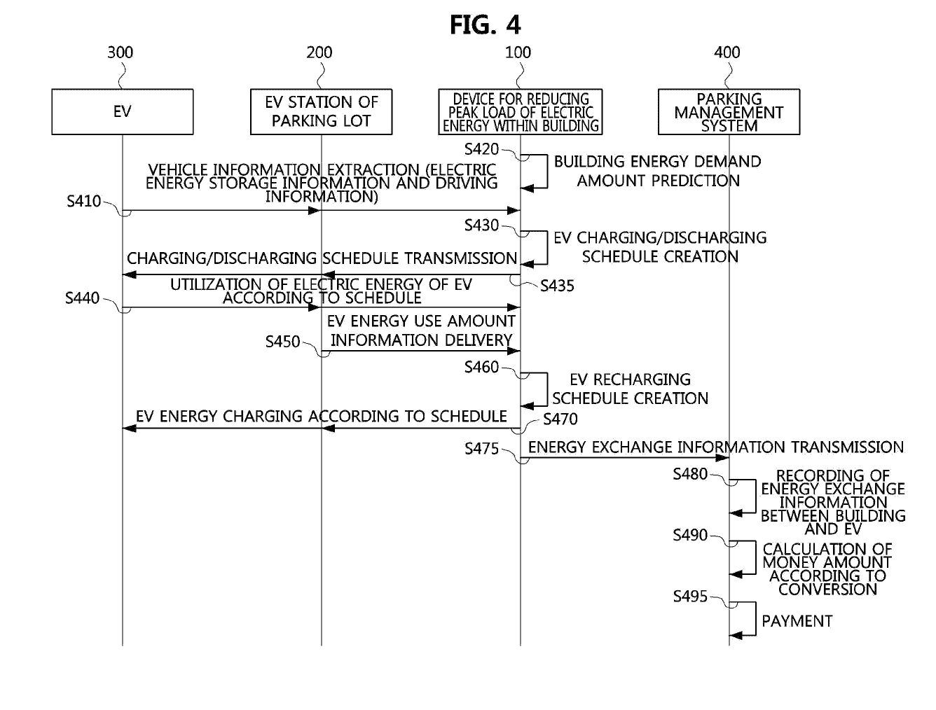

FIG. 4 is a flowchart illustrating a method of reducing a peak load of electric energy within a building and its detailed steps according to an example embodiment of the present invention.

Referring to FIG. 4, the method of reducing the peak load of the electric energy within the building may include a vehicle information extraction step S410 of extracting vehicle information of the EV 300 though a connection to the EV 300, an energy demand amount prediction step S420 of predicting a demand amount of the electric energy within the building, and a charging/discharging schedule determination step S430 of determining a charging/discharging schedule of the EV 300 based on the vehicle information and the demand amount of the electric energy within the building. The vehicle information may include electric energy storage information and driving information of the EV 300.

A demand amount of electric energy within the building 10 may be calculated based on an energy management plan of the building 10. A demand amount response (DR) information of the building 10, existing energy use information, and information about an energy use amount per previous unit time, and the like may be referred to as information used for predicting the demand amount of the electric energy.

Referring to FIG. 2 again, the EV 300 may be parked in the building 10 for getting into office in the morning of the next day and connected to a charging/discharging socket of a parking lot of the building after the EV 300 is charged in a nighttime zone in which a load of electric energy is small. At this time, the vehicle information such as the electric energy storage information and the driving information of the EV 300 may be transferred to the device 100 for reducing the peak load of the electric energy within the building 10.

The electric energy storage information may include information (maximum capacity) about an amount of electric energy with which the EV 300 may be fully charged, information about a current amount of charge of electric energy, information (charge/discharge amount per unit time) about a time required for charging/discharging with electric energy, and information about a charge/discharge amount history specific to a previous unit period.

The driving information may include driving distance information at the time of getting into office and getting out of office, daily driving pattern information, and fuel efficiency information.

In the charging/discharging schedule determination step S430, a total amount of electric energy capable of being supplied from the EV 300 in a demand amount of electric energy within the building may be calculated and the total amount of electric energy capable of being supplied may be calculated based on the electric energy storage information and the driving information of the EV 300.

In the energy demand amount prediction step S420, electric energy to be used in the building 10 today may be predicted based on the vehicle information collected according to each EV 300. In the charging/discharging schedule determination step S430, a function of analyzing a total amount of electric energy available through electric energy with which the EVs 300 are charged is performed. Because detailed description of the function has been given above, redundant description thereof is omitted.

The method of reducing the peak load of the electric energy within the building may further include a building energy storage step S440 of receiving electric energy of the EV 300 from the electric storage facility of the building 10 based on the charging/discharging schedule when the peak load of the electric energy within the building occurs after the charging/discharging schedule determination step S430.

The device for reducing the peak load of the electric energy within the building may transfer the determined charging/discharging schedule to the EV 300 through the EV station of the parking lot (S435). The user of the EV 300 may approve or reject the transferred charging/discharging schedule of the EV 300.

The occurrence of the peak load may be determined when a demand amount of electric energy is greater than a predetermined threshold value after the predetermined threshold value is specified. That is, when the demand amount of electric energy substantially reaches a maximum amount, the occurrence of the peak load may be determined Because the determination of the occurrence of the peak load has been described in detail above, redundant description thereof is omitted.

The method of reducing the peak load of the electric energy within the building may further include a building energy discharge step S470 of causing the electric energy of the electric storage facility to be provided to the EV 300 based on an amount of the received electric energy of the EV 300 after the building energy storage step S440.

The step S470 of providing the electric energy stored in the electric storage facility of the building becomes a charging or recharging procedure when viewed from the EV 300. Even when the EV 300 is recharged with electric energy, a recharging schedule is created based on vehicle information and electric energy storage information (S460), and the EV 300 may be recharged based on the recharging schedule.

The device for reducing the peak load of the electric energy within the building may cause the EV 300 to be charged with electric energy of the electric storage facility based on an amount of electric energy received from the EV 300. After a peak load time, a recharging procedure may be performed based on an amount of electric energy received from the EV 300 (S450) when the electric energy of the EV 300 is utilized as electric energy within the building. This progresses in the form in which each EV 300 is charged with electric energy by making a schedule considering the time of getting out of office based on each EV-specific charging time previously collected. That is, a recharging schedule is created based on vehicle information and electric energy storage information even at the time of recharging and a recharging operation may be performed based on the created recharging schedule.

The method of reducing the peak load of the electric energy within the building may further include an energy exchange information recording step S480 of recording electric energy exchange information between the building and the EV 300. In addition, the method may further include a conversion amount calculation step S490 of calculating an amount of money to be paid to a user of the EV based on the electric energy exchange information after the energy exchange information recording step S480.

An operation in which electric energy of the EV 300 is utilized and the EV 300 is recharged according to the charging/discharging schedule as described above may be recorded as an electric energy use history of the EV 300 by the energy exchange information management section 150. That is, the device for reducing the peak load of the electric energy within the building enables the energy exchange information to be managed by transferring the energy exchange information to the parking management system (S475). In addition, a parking fee is calculated and the calculated parking fee is subtracted from an amount of money into which used electric energy is converted for the user of the EV 300 in conjunction with the parking management system when the user of the EV 300 gets out of office (S495). Specific description thereof has been described above.

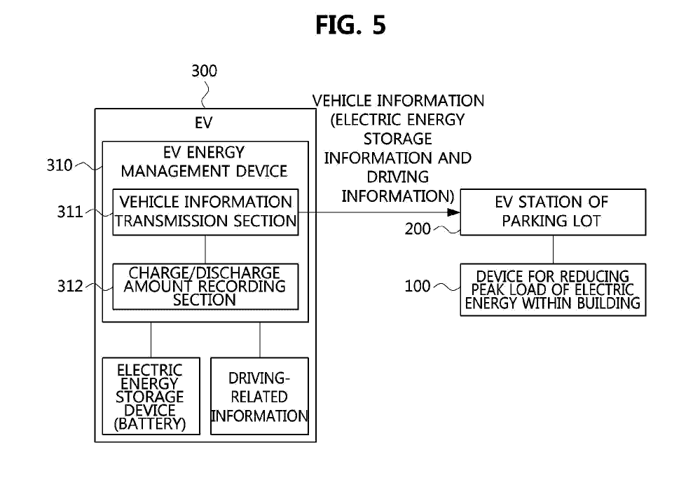

FIG. 5 is a block diagram illustrating an EV energy management device 310 and its components according to an example embodiment of the present invention.

Referring to FIG. 5, the EV energy management device 310 may include a vehicle information transmission section 311 connected to a charging/discharging socket and configured to transmit vehicle information of the EV 300 to the device 100 for reducing the peak load of the electric energy within the building, and a charge/discharge amount recording section 312 configured to record an amount of charge or discharge of electric energy through the charging/discharging socket and calculate a total amount of electric energy in predetermined period units. In addition, the vehicle information includes electric energy storage information and driving information of the EV 300.

The EV energy management device 310 may be driven by a processor provided inside the EV 300. That is, embodiments of the EV energy management device 310 may be performed as program codes or a computer program product having the program codes. Although the program codes may be executed by a processor provided inside the EV 300 as described above or executed by a processor of a computing device including the program codes, the program codes may be executed by an independent separate processor.

The possible information exchange by a wired/wireless communication network among the EV 300, the EV station 200 of the parking lot, the device 100 for reducing the peak load of the electric energy, and the parking management system 400 has been described above with reference to FIG. 1. Other components within the building will be described with reference to FIG. 1.

The vehicle information transmission section 311 may extract and transmit driving-related information 320 inside the EV 300 and driving information from an electric energy storage device (battery) 330. The charge/discharge amount recording section 312 may record the amount with respect to the exchange of electric energy with outside and calculate a total amount hourly or daily. The total amount calculated hourly or daily may be referred to when an amount of money into which electric energy is converted is calculated between the user of the EV 300 and a building operator.

Although several aspects of the present invention were explained from aspects of devices, it is clear that such the aspects may also be applied to corresponding methods. That is, each step constituting the method may correspond to operations of one or more components constituting the corresponding device. The example embodiments of the present invention may be implemented by hardware or software. The example embodiments of the present invention may be implemented as program codes or a computer program product having the program codes.

While the example embodiments of the present invention and their advantages have been described in detail, it should be understood that various changes, substitutions and alterations may be made herein without departing from the scope of the invention.

What is claimed is:

1. A device for reducing a peak load of electric energy within a building, the device comprising:
for control of the electric energy within the building using electric energy of an electric vehicle (EV),
a vehicle information extraction section connected to the EV and configured to extract vehicle information of the EV;
an energy demand amount prediction section configured to predict a demand amount of the electric energy within the building; and
a charging/discharging schedule determination section configured to determine a charging/discharging schedule of the EV based on the vehicle information and the demand amount of the electric energy within the building.

2. The device of claim 1, wherein the vehicle information includes electric energy storage information and driving information of the EV.

3. The device of claim 1, wherein the charging/discharging schedule determination section calculates a total amount of electric energy capable of being supplied from the EV in the demand amount of the electric energy within the building.

4. The device of claim 3, wherein the total amount of electric energy capable of being supplied is calculated based on the electric energy storage information and driving information of the EV.

5. The device of claim 1, further comprising:
an energy exchange section configured to receive the electric energy of the EV from an electric storage facility of the building based on the charging/discharging schedule when the peak load of the electric energy within the building occurs.

6. The device of claim 5, wherein the energy exchange section causes the EV to be charged with the electric energy of the electric storage facility based on an amount of the electric energy received from the EV.

7. The device of claim 1, further comprising:
an energy exchange information management section configured to record electric energy exchange information between the building and the EV.

8. The device of claim 7, wherein the energy exchange information management section calculates an amount of money to be paid to a user of the EV based on the electric energy exchange information.

9. A method of reducing a peak load of electric energy within a building in a device for controlling the electric energy within the building using electric energy of an EV, the method comprising:
extracting vehicle information of the EV though a connection to the EV;
predicting a demand amount of the electric energy within the building; and
determining a charging/discharging schedule of the EV based on the vehicle information and the demand amount of the electric energy within the building.

10. The method of claim 9, wherein the vehicle information includes electric energy storage information and driving information of the EV.

11. The method of claim 9, wherein the determining of the charging/discharging schedule includes:
calculating a total amount of electric energy capable of being supplied from the EV in the demand amount of the electric energy within the building.

12. The method of claim 11, wherein the total amount of electric energy capable of being supplied is calculated based on the electric energy storage information and driving information of the EV.

13. The method of claim 9, further comprising:
after the determining of the charging/discharging schedule,
receiving the electric energy of the EV from an electric storage facility of the building based on the charging/discharging schedule when the peak load of the electric energy within the building occurs.

14. The method of claim 13, further comprising:
after the receiving of the electric energy of the EV from the electric storage facility of the building,
causing the electric energy of the electric storage facility to be provided to the EV based on an amount of the received electric energy of the EV.

15. The method of claim 9, further comprising:
recording electric energy exchange information between the building and the EV.

16. The method of claim 15, further comprising:
after the recording of the electric energy exchange information,
calculating an amount of money to be paid to a user of the EV based on the electric energy exchange information.

17. A device for managing electric energy of an EV, the device comprising:
a vehicle information transmission section connected to a charging/discharging socket and configured to transmit vehicle information of the EV to a device for reducing a peak load of electric energy within a building; and
a charge/discharge amount recording section configured to record an amount of charge or discharge of electric energy through the charging/discharging socket and calculate a total amount of electric energy in predetermined period units.

18. The device of claim 17, wherein the vehicle information includes electric energy storage information and driving information of the EV.
